(19) United States
(12) Patent Application Publication
(10) Pub. No.: US 2017/0264212 A1
(43) Pub. Date: Sep. 14, 2017

(54) VERIFYING SYSTEM AND METHOD FOR VERIFYING THE DISCONNECTING MEANS OF A DC/AC CONVERTER

(71) Applicant: INGETEAM POWER TECHNOLOGY, S.A., Zamudio (Bizkaia) (ES)

(72) Inventors: Luis MUGUERZA OLCOZ, Sarriguren (ES); Julian BALDA BELZUNEGUI, Sarriguren (ES); Mikel BORREGA AYALA, Sarriguren (ES); Roberto GONZALEZ SENOSIAIN, Sarriguren (ES)

(73) Assignee: INGETEAM POWER TECHNOLOGY, S.A., Zamudio (Bizkaia) (ES)

(21) Appl. No.: 15/329,951

(22) PCT Filed: Jul. 29, 2014
(86) PCT No.: PCT/ES2014/070612

§ 371 Date: Jan. 27, 2017

(51) Int. Cl. H02M 7/44; G01R 31/04; H02M 1/084

(52) U.S. Cl. CPC H02M 7/44; H02M 1/084; G01R 31/04

(57) ABSTRACT

Verifying system and method for verifying the disconnecting means of a DC/AC converter which are connected in series through a midpoint in each phase between the converter and a power grid. The system comprises voltage detectors and a control unit in communication with said detectors and configured for determining the status of the disconnecting means depending on said voltages. The detectors comprise a detector associated with each phase for measuring the voltages between the corresponding midpoint and the neutral of the power grid, and an additional detector for measuring the voltage between said neutral and a reference point of the converter.

### TECHNICAL FIELD

The main field of application of the present invention is in the industry dedicated to designing electronic devices and, more particularly, electronic devices intended for being used in the sector of power systems for photovoltaic solar energy conversion. The invention may also be applicable in other fields such as wind power generation, power generation by means of electrochemical cells or other devices that provide continuous power.

### PRIOR ART

Grid-connected photovoltaic installations are formed by an array of photovoltaic panels (photovoltaic generator) and an electronic direct current-alternating current (DC/AC) converter, also known as an inverter, conditioning the continuous power produced by the panels, converting it into alternative energy and injecting it to the power grid. This photovoltaic inverter is connected to and disconnected from the distribution grid through disconnecting means, such as relays or contactors, for example. These means must uncouple from the inverter of the grid in response to an alarm situation or when the inverter is OFF, therefore assuring the insulation between the power grid and the photovoltaic installation.

Certain photovoltaic inverter electrical safety standards, such as IEC 62109 (Safety of power converters for use in photovoltaic power systems) require installing these disconnecting means in the inverters. In inverters without transformer, the standard requires the use of two disconnecting means arranged in series by phase. They also require verifying the correct opening and closing of said means. This verification must be performed at least every time the inverter makes a connection with the power grid.

Personal safety may be affected if malfunction of the disconnecting means occurs, for example, the contacts of a disconnecting system are welded together and do not establish disconnection from the power grid. For this reason, the inverter must be capable of detecting the correct operation of these disconnecting means.

There are different methods for detecting defect in a disconnecting system. In an inverter with double disconnecting system, a typical method consists of taking six voltage measurements, three of them on the grid side and three of them between the different disconnecting means of one and the same phase (for each phase). An example of this system is disclosed in document US20100226160A1, where, for each phase, on one hand, the voltage between the midpoint between two serially connected systems and a reference point of the inverter is measured, and on the other hand, the voltage between the neutral of the grid and the output of the system connected to the grid is measured. This document therefore discloses a method that requires using six voltage measurements, with their six corresponding voltage meters or detectors to verify for the correct operation of the disconnecting means. Each of these meters involves the inclusion of a signal processing hardware affecting the final cost of the inverter.

### DISCLOSURE OF THE INVENTION

An object of the invention is to provide a verifying system for verifying the status of disconnecting means arranged between a three-phase DC/AC converter and a power grid, as described in the claims.

The verifying system of the invention is used for verifying the status of disconnecting means arranged between a three-phase DC/AC converter and a power grid, status of the disconnecting means being understood as whether or not said disconnecting means work correctly. Each phase comprises two disconnecting means arranged in series between the grid and the three-phase DC/AC converter. The system comprises a plurality of voltage detectors and a control unit which is communicated with the plurality of voltage detectors to receive the voltages measured by said detectors and which is configured to determine the status of the disconnecting means depending on said voltages.

The plurality of voltage detectors comprises a voltage detector associated with each phase for measuring the voltages between the midpoint of the disconnecting means corresponding to each phase and the neutral of the power grid, and an additional voltage detector for measuring the voltage between the neutral of the power grid and a reference point of the DC converter side.

Therefore, as a result of measuring the voltage at the midpoints of each phase and of measuring the voltage between the neutral of the power grid and the reference point of the converter, said measured voltages at the midpoints can be associated both with the power grid and the converter, which allows verifying all the disconnecting means (both those which are on the converter side and those which are on the power grid side), with a smaller number of detectors (four) than that used in the state of the art (six), with the advantages that it entails in terms of cost and simplicity in design, for example.

Another object of the invention is to provide a verifying method for verifying the status of disconnecting means arranged between a three-phase DC/AC converter and a power grid, as described in the claims.

The verifying method of the invention is used for verifying the status of disconnecting means arranged between a three-phase DC/AC converter and a power grid, status of the disconnecting means being understood as whether or not said disconnecting means work correctly. In the method, the phase voltage between the midpoint of the three phases and the neutral of the power grid is measured, the reference voltage between the neutral of the power grid and the reference point of the converter is measured, and the status of the disconnecting means is determined taking into account the measured voltages. At least the advantages described for the verifying system of the invention are obtained with the method of the invention.

These and other advantages and features of the invention will become evident in view of the drawings and the detailed description of the invention.

### DESCRIPTION OF THE DRAWINGS

FIG. 1 schematically shows an embodiment of the verifying system of the invention.

FIG. 2 shows a block diagram of a preferred embodiment of the method of the invention.

FIG. 3 schematically shows the system of FIG. 1 in which the external disconnecting means of one phase have a defect.

FIG. 4 schematically shows the system of FIG. 1 in which the internal disconnecting means of one phase have a defect.

### DETAILED DISCLOSURE OF THE INVENTION

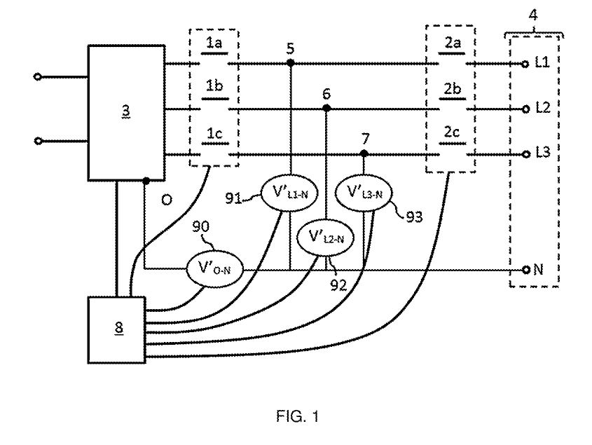

A first aspect of the invention relates to a verifying system for verifying disconnecting means 1a, 1b, 1c, 2a, 2b and 2c arranged between a three-phase DC/AC converter 3 and a power grid 4. In each phase L1, L2 and L3, there are arranged two disconnecting means 1a and 2a, 1b and 2b , and 1c and 2c connected in series through a corresponding midpoint 5, 6 and 7, as shown in FIG. 1, for example. Hereinafter, those disconnecting means which are on the side of the three-phase DC/AC converter 3 (between the respective midpoints 5, 6 and 7 and the three-phase DC/AC converter 3) are called internal disconnecting means 1a, 1b and 1c, and those disconnecting means which are on the side of the power grid 4 (between the respective midpoints 5, 6 and 7 and the power grid 4) are called external disconnecting means 2a, 2b and 2c.

The system comprises a plurality of voltage detectors 90, 91, 92 and 93 and a control unit 8 which is communicated with the detectors 90, 91, 92 and 93 to receive the respective voltages V′_{O-N}, V′_{L1-N}, V′_{L2-N} and V′_{L3-N} measured by said plurality of detectors 90, 91, 92 and 93 and which is configured to determine the status of the disconnecting means 1a, 1b, 1c, 2a, 2b and 2c depending on said voltages V′_{O-N}, V′_{L1-N}, V′_{L2-N} and V′_{L3-N}. The plurality of voltage detectors 90, 91, 92 and 93 comprises a respective voltage detector 91, 92 and 93 associated with each phase L1, L2 and L3 between the midpoint 5, 6 and 7 corresponding to each phase L1, L2 and L3 and the neutral N of the power grid 4 for measuring the phase voltages V′_{L1-N}, V′_{L2-N} and V′_{L3-N}, and an additional voltage detector 90 between the neutral N of the power grid 4 and a reference point O of the DC side of the three-phase DC/AC converter 3 for measuring the reference voltage V′_{O-N}. Therefore, an efficient verification can be achieved with the system of the invention using a smaller number of voltage detectors (four) in comparison with the number used in the state of the art (six).

The control unit 8 is also communicated with the disconnecting means 1a, 1b, 1c, 2a, 2b and 2c to enable controlling the opening and closing of said disconnecting means 1a, 1b, 1c, 2a, 2b and 2c and is furthermore configured for combining in a specific manner the measured voltages V′_{L1-N}, V′_{L2-N}, V′_{L3-N} and V′_{O-N} and the control of the disconnecting means 1a, 1b, 1c, 2a, 2b and 2c for the purpose of verifying whether or not said disconnecting means 1a, 1b, 1c, 2a, 2b and 2c work correctly depending on said combination.

The three-phase DC/AC converter 3 comprises a plurality of semiconductor-type switches (not depicted in the drawings), the control unit 8 also being configured for controlling the opening and closing of said switches of the three-phase DC/AC converter 3. When verifying the status of the disconnecting means 1a, 1b, 1c, 2a, 2b and 2c, said control is linked to the voltages V′_{L1-N}, V′_{L2-N}, V′_{L3-N} and V′_{O-N} measured by the plurality of respective voltage detectors 91, 92, 93 and 90 and to the control over the opening and closing of the disconnecting means 1a, 1b, 1c, 2a, 2b and 2c in a controlled manner.

The internal disconnecting means 1a, 1b, 1c can be controlled by a single signal from the control unit 8 (all disconnecting means being controlled by the same signal) or by three independent signals from the control unit 8 (each disconnecting means being controlled by one signal). Similarly, the external disconnecting means 2a, 2b and 2c can be controlled by a single signal from the control unit 8 (all disconnecting means being controlled by the same signal) or by three independent signals from the control unit 8 (each disconnecting means being controlled by one signal).

The reference point O can be the negative of the DC side of the three-phase DC/AC converter 3, the positive of said DC side or an intermediate point between said positive and said negative, whereby allows obtaining a known voltage per phase L1, L2 and L3 on the side of the three-phase DC/AC converter 3 in reference to said three-phase DC/AC converter 3. In the case in which the reference point O corresponds with an intermediate point between the positive and the negative of the DC side of the three-phase DC/AC converter 3, the system further comprises a dividing branch (not depicted in the drawings) in said DC side arranged between said positive and said negative, which preferably is a capacitive divider which is preferably formed by two capacitors connected in series, the intermediate point serving as a reference point corresponding with the point of connection P between the two capacitors. The capacitors preferably comprise one and the same capacity.

A second aspect of the invention relates to a verifying method for verifying the status of disconnecting means arranged between a three-phase DC/AC converter 3 and a power grid 4, which is implemented by means of a control unit 8, two disconnecting means 1a, 1b, 1c, 2a, 2b and 2c being connected in series through a midpoint 5, 6 and 7 in each phase L1, L2 and L3. The method aims to verify whether or not the disconnecting means 1a, 1b, 1c, 2a, 2b and 2c work correctly.

In the verifying method, the phase voltage V′_{L1-N}, V′_{L2-N} and V′_{L3-N} between the midpoint 5, 6 and 7 of the three phases L1, L2 and L3 and the neutral N of the power grid 4 is measured, the reference voltage V′_{O-N} between the neutral N of the power grid 4 and the reference point O of the three-phase DC/AC converter 3 is measured, and whether or not the disconnecting means 1a, 1b, 1c, 2a, 2b and 2c work correctly is determined taking into account the measured voltages V′_{L1-N}, V′_{L2-N}, V′_{L3-N} and V′_{O-N}. Therefore, as a result of both the phase voltages V′_{L1-N}, V′_{L2-N} and V′_{L3-N} and of the reference voltage V′_{O-N}, said measured voltages V′_{L1-N}, V′_{L2-N}, V′_{L3-N} and V′_{O-N} can be associated both with the power grid 4 and the three-phase DC/AC converter 3, which allows verifying all the disconnecting means 1a, 1b, 1c, 2a, 2b and 2c with a smaller number of detectors (four) than that used in the state of the art (six), with the advantages that it entails in terms of cost and simplicity in design, for example.

With the method, the status of the external disconnecting means 2a, 2b and 2c is verified taking into account only the phase voltages V′_{L1-N}, V′_{L2-N} and V′_{L3-N}, and the status of the internal disconnecting means 1a, 1b and 1c is verified taking into account the sum of said phase voltages V′_{L1-N}, V′_{L2-N} and V′_{L3-N} and the reference voltage V′_{O-N}, the phase voltages V′_{L1-N}, V′_{L2-N} and V′_{L3-N} on the side of the three-phase DC/AC converter 3 being associated by means of said sums.

In order to determine the status of the disconnecting means 1a, 1b, 1c, 2a, 2b and 2c, a specific opening and closing sequence is applied on the disconnecting means 1a, 1b, 1c, 2a, 2b and 2c, a control over the three-phase DC/AC converter 3 is also performed in which said three-phase DC/AC converter 3 is prevented from generating an alternating voltage during at least one time interval when carrying out the method and in which said three-phase DC/AC converter 3 is allowed to generate a known alternating voltage during at least one time interval when carrying out the method, the measured voltages V′_{L1-N}, V′_{L2-N} , V′_{L3-N} and V′_{O-N}, the specific opening and closing sequence on the disconnecting means 1a, 1b, 1c, 2a, 2b and 2c and the control over the three-phase DC/AC converter 3 being combined in a specific manner.

In a preferred embodiment of the method, the opening and closing sequence of the disconnecting means 1a, 1b, 1c, 2a, 2b and 2c, the measured voltages V′_{L1-N}, V′_{L2-N}, V′_{L3-N} and V′_{O-N} and the control over the three-phase DC/AC converter 3 are linked in the following manner:

The method comprises an external verification step Ee in which the status of the external disconnecting means 2a, 2b , 2c is verified, comprising the following steps:
opening, by means of the control unit 8, all the disconnecting means 1a, 1b, 1c, 2a, 2b and 2c (or keeping them open if they are already open);
measuring the phase voltages V′_{L1-N}, V′_{L2-N} and V′_{L3-N} with the corresponding detectors 91, 92 and 93;
comparing, preferably with the control unit 8, each of said phase voltages V′_{L1-N}, V′_{L2-N} and V′_{L3-N} with a predetermined external threshold value Te; and
determining, by means of the control unit 8, the malfunction of one of the external disconnecting means 2a, 2b and 2c if the phase voltage V′_{L1-N}, V′_{L2-N} , or V′_{L3-N} associated with its phase L1, L2 or L3 is greater than the predetermined external threshold value Te. If the associated phase voltage V′_{L1-N}, V′_{L2-N} or V′_{L3-N} of a phase L1, L2 or L3 is approximately zero (or below the external threshold value Te), the control unit 8 assumes that there is either no voltage in the power grid 4, or that the operation of said external disconnecting means 2a, 2b and 2c is correct (at least in terms of the opening thereof).

The predetermined external threshold value Te is linked to the rated voltage of the power grid 4, being able to correspond, for example, with 80% of said rated voltage. Below said value, it is considered that there is no power grid 4.

The method further comprises an internal verification step Ei in which the status of the internal disconnecting means 1a, 1b and 1c is verified, comprising the following steps:
opening, by means of the control unit 8, all the disconnecting means 1a, 1b, 1c, 2a, 2b and 2c (or keeping them open if they are already open);
generating, by means of an order preferably from the control unit 8, a known alternating voltage by means of the three-phase DC/AC converter 3;
measuring the phase voltages and V′_{L1-N}, V′_{L2-N}, V′_{L3-N} between each phase L1, L2 and L3 and the neutral N of the power grid 4 with the corresponding detectors 91, 92 and 93;
measuring the reference voltage V′_{O-N} between the neutral N of the power grid 4 and the reference point O of the three-phase DC/AC converter 3 with the corresponding additional detector 90;
adding, preferably with the control unit 8, the reference voltage V′_{O-N} to each of the phase voltages V′_{L1-N}, V′_{L2-N} and V′_{L3-N}, a voltage phase—reference point O for each phase L1, L2 and L3 thus being obtained;
comparing, preferably with the control unit 8, the result of each sum with a predetermined internal threshold value Ti, said internal threshold value Ti being equal to or less than the alternating voltage generated by the three-phase DC/AC converter 3; and
determining, with the control unit 8, the malfunction of one of the internal disconnecting means 1a, 1b and 1c if the result of the sum corresponding to its phase L1, L2 or L3 is greater than the predetermined internal threshold value Ti. If the result of the sum is approximately zero (or less than the internal threshold value Ti), the control unit 8 assumes that either the three-phase DC/AC converter 3 does not work correctly or the operation of the internal disconnecting means 1a, 1b or 1c of the corresponding phase L1, L2 or L3 is correct (at least in terms of the opening thereof).

The predetermined internal threshold value Ti is linked to the alternating voltage generated with the converter, being able to correspond, for example, with 80% of said voltage.

The verification steps Ee and Ei allows determining mainly if the disconnecting means 1a, 1b, 1c, 2a, 2b and 2c work correctly when they are opened, and the method further comprises an additional verification step Ea to determine if said internal disconnecting means 1a, 1b and 1c also work correctly when they are closed. Said additional verification method Ea comprises the following steps:
closing, by means of the control unit 8, the internal disconnecting means 1a, 1b and 1c (or keeping them closed if they were already closed);
causing, by means of an order preferably from the control unit 8, the generation a known alternating voltage by means of the three-phase DC/AC converter 3;
measuring the phase voltages V′_{L1-N}, V′_{L2-N} and V′_{L3-N} between each phase L1, L2 and L3 and the neutral N of the power grid 4 with the corresponding detectors 91, 92 and 93;
measuring the reference voltage V′_{O-N} between the neutral N of the power grid 4 and the reference point O of the three-phase DC/AC converter 3 with the corresponding additional detector 90;
adding, preferably with the control unit 8, the reference voltage V′_{O-N} to each of the phase voltages V′_{L1-N}, V′_{L2-N} and V′_{L3-N}, a voltage phase—reference point O for each phase L1, L2 and L3 thus being obtained;
comparing, preferably with the control unit 8, the result of each sum with a predetermined additional threshold value Ta, said additional threshold value Ta being equal to or less than the alternating voltage generated by the three-phase DC/AC converter 3; and
determining, with the control unit 8, the malfunction of one of the internal disconnecting means 1a, 1b and 1c if the result of the sum corresponding to its phase L1, L2 or L3 is less than the predetermined additional threshold value Ta. If the result of the sum exceeds the predetermined additional threshold value Ta, the control unit 8 assumes that the three-phase DC/AC converter 3 works correctly and that the operation of the corresponding internal disconnecting means 1a, 1b or 1c is correct.

The additional threshold value Ta preferably corresponds with the internal threshold value Ti.

The method further comprises a final verification step Ef comprising the following steps:
opening, by means of the control unit 8, the internal disconnecting means 1a, 1b and 1c, while at the same time closing the external disconnecting means 2a, 2b and 2c or keeping them closed;
measuring the phase voltages V′_{L1-N}, V′_{L2-N} and V′_{L3-N} between each phase L1, L2 and L3 and the neutral N of the power grid 4 with the corresponding detectors 91, 92 and 93;
comparing each of said phase voltages V′_{L1-N}, V′_{L2-N} and V′_{L3-N} with a predetermined final threshold value Tf; and
determining that the external disconnecting means 2a, 2b and 2c work correctly if their corresponding measured voltage exceeds the predetermined final threshold value Tf, while at the same time determining that the power grid 4 is connected.

The final threshold value Tf preferably corresponds with the external threshold value Te.

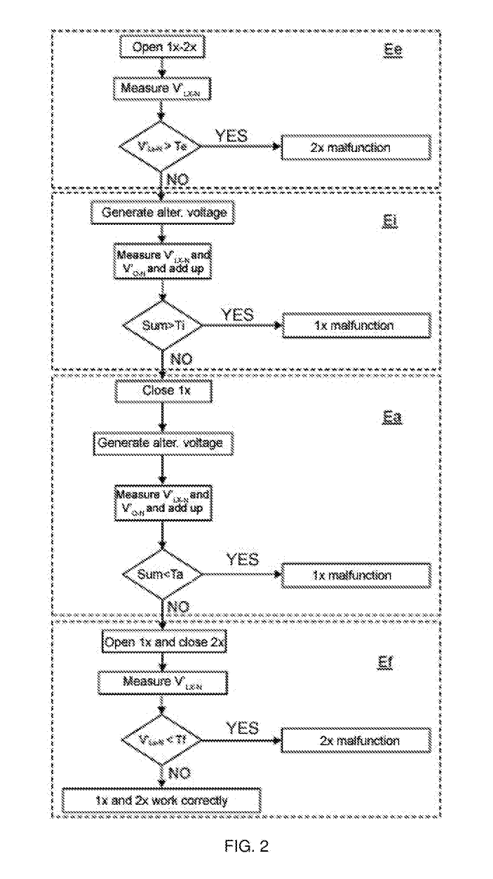

The order for carrying out the steps in the preferred embodiment is as follows: the external verification step Ee is carried out first, followed by the internal verification step Ei, the additional verification step Ea and finally the final verification step Ef; as shown in FIG. 2. This order for carrying out the steps is non-limiting, and it may vary in other embodiments.

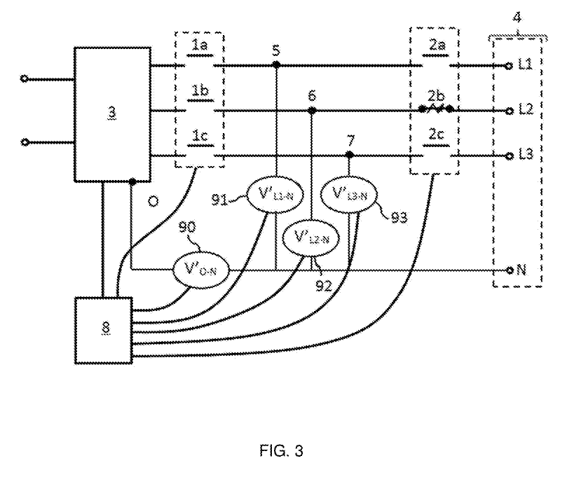

Next and by way of example, the identification of the malfunction of one of the external disconnecting means 2a, 2b and 2c with the method of the invention (particularly with the preferred embodiment of the method) is described, which in this example corresponds with the disconnecting means 2b of the phase L2 as shown in FIG. 3, where it is shown that the contacts of said disconnecting means 2b have been short-circuited. As a result, despite the control unit 8 orders said disconnecting means 2b to open, they remain closed at all times.

The external verification step Ee is carried out first. The control unit 8 orders all the disconnecting means 1a, 1b, 1c, 2a, 2b and 2c to open (as described, due to a malfunction, the disconnecting means 2b remain closed, said situation not being yet identified) and the phase voltages V′_{L1-N}, V′_{L2-N} and V′_{L3-N} are detected. Since the external disconnecting means 2b of the phase L2 is closed, the control unit 8 detects that the corresponding phase voltage V′_{L2-N} is above the predetermined external threshold value Te and determines a malfunction of the external disconnecting means associated with said phase (in this case the external disconnecting means 2b associated with the phase L2). The method can continue being implemented for determining whether or not the internal disconnecting means 1a, 1b and 1c and the other external disconnecting means 2a and 2c work correctly.

Next and by way of example, the detection of the malfunction of internal disconnecting means 1a, 1b and 1c with the method of the invention (particularly with the preferred embodiment of the method) is described, which in this example correspond with the internal disconnecting means 1c of the phase L3 as shown in

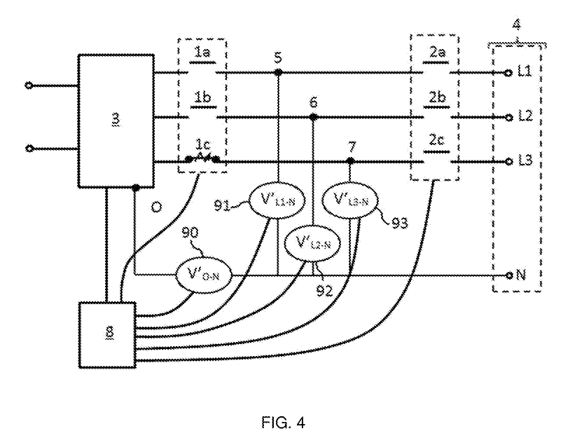

FIG. 4, where it is shown that the contacts of said internal disconnecting means lc have been short-circuited. As a result, despite the control unit 8 orders said internal disconnecting means lc to open, they remain closed.

The external verification step Ee is carried out first. The control unit 8 orders all the disconnecting means 1a, 1b, 1c, 2a, 2b and 2c to open (as described, due to a malfunction, the internal disconnecting means lc remain closed, said situation not being yet identified) and the phase voltages V′_{L1-N}, V′_{L2-N} and V′_{L3-N} measured by the corresponding detectors 91, 92 and 93 are detected. Since all the external disconnecting means 2a, 2b and 2c were opened (it is assumed that all the external disconnecting means 2a, 2b and 2c work correctly for this example), the control unit 8 detects that the phase voltages V′_{L1-N}, V′_{L2-N} and V′_{L3-N} are equal to approximately zero and do not detect any anomaly therein.

The internal verification step Ei is carried out after the external verification step Ee.

The control unit 8 orders the three-phase DC/AC converter 3 to generate a known alternating voltage, the voltages V′_{L1-N}, V′_{L2-N}, V′_{L3-N} and V′_{L3-N} are measured, and the reference voltage V′_{L3-N} is added to each of the phase voltages V′_{L1-N}, V′_{L2-N} and V′_{L3-N}. Given that the internal disconnecting means lc of the phase L3 have been short-circuited, the sum of the voltages V′_{L3-N} and V′_{O-N} is above the internal threshold value Ti, and the control unit 8 determines the malfunction of said internal disconnecting means 1c. The method can continue being implemented for determining whether or not the external disconnecting means 2a, 2b and 2c and the other internal disconnecting means la and lc work correctly.

1-14. (canceled)

15. A verifying system for verifying disconnection of a three-phase DC/AC converter by two disconnecting devices connected in series through a midpoint in each phase between the three-phase DC/AC converter and a power grid, the verifying system comprising:
a plurality of voltage detectors, comprising,
a voltage detector associated with each phase, respectively, configured to measure the phase voltages between each midpoint and the neutral of the power grid,
an additional voltage detector configured to measure a reference voltage between the neutral of the power grid and a reference point of the DC side of the three-phase DC/AC converter, and
a control unit which is in communication with said plurality of voltage detectors and configured to receive the measured voltages and determine the status of the disconnecting devices depending on said received voltages.

16. The verifying system according to claim 15, wherein the control unit is in communication with the disconnecting devices and is configured to control the opening and closing of said disconnecting devices, to combine in a specific manner the measured voltages and the control of the opening and closing of said disconnecting devices, and to determine the status of the disconnecting devices depending on said combination.

17. The verifying system according to claim 16, wherein the three-phase DC/AC converter comprises a plurality of semiconductor-type switches, the control unit configured to control the opening and closing of said switches of the three-phase DC/AC converter, the control of said switches being linked to the measured voltages and to the control of the opening and closing of said disconnecting devices in a controlled manner to determine the status of the disconnecting devices.

18. The verifying system according to claim 16, wherein the reference point corresponds with a positive of the DC side of the three-phase DC/AC converter.

19. The verifying system according to claim 16, wherein the disconnecting devices arranged between the midpoints and the three-phase DC/AC converter correspond to internal disconnecting devices and are all controlled by a signal from the control unit.

20. The verifying system according to claim 16, wherein the disconnecting devices arranged between the midpoints and the power grid correspond to external disconnecting devices and are controlled by a signal from the control unit.

21. The verifying system according to claim 16, wherein the reference point corresponds with a negative of the DC side of the three-phase DC/AC converter.

22. The verifying system according to claim 16, wherein the reference point corresponds with an intermediate point between the positive and the negative of the DC side of the three-phase DC/AC converter.

23. The verifying system according to claim 16, wherein the disconnecting devices arranged between the midpoints and the three-phase DC/AC converter correspond to internal disconnecting devices and are all controlled by three independent signals from the control unit.

24. The verifying system according to claim 16, wherein the disconnecting devices arranged between the midpoints and the power grid correspond to external disconnecting devices and are controlled by three independent signals from the control unit.

25. A verifying method for verifying disconnection of a three-phase DC/AC converter by two disconnecting devices connected in series through a midpoint in each phase between the three-phase DC/AC converter and a power grid, comprising:
measuring the phase voltage between the midpoint of the three phases and the neutral of the power grid,
measuring a reference voltage between the neutral of the power grid and a reference point of the three-phase DC/AC converter, and
determining a status of the disconnecting devices taking into account the measured voltages.

26. The verifying method according to claim 25, wherein the disconnecting devices arranged between the midpoints and the three-phase DC/AC converter correspond to internal disconnecting devices and wherein the disconnecting devices arranged between the midpoints and the power grid correspond to external disconnecting means, only the phase voltages being taken into account to verify the status of the external disconnecting devices and the sum of each of said phase voltages and the reference voltage being taken into account to verify the status of the internal disconnecting devices.

27. The verifying method according to claim 26, wherein in order to determine the status of the disconnecting devices a specific opening and closing sequence is applied to the disconnecting devices and a control over the three-phase DC/AC converter is performed in which said three-phase DC/AC converter is prevented from generating an alternating voltage during at least a first time interval when carrying out the method and in which said three-phase DC/AC converter is allowed to generate a known alternating voltage during at least a second time interval when carrying out the method, the measured voltages, the specific opening and closing sequence of the disconnecting devices, and the control over the three-phase DC/AC converter being combined in a specific manner.

28. The verifying method according to claim 27, further comprising:
an external verification step in which all the disconnecting devices are opened or kept open;
measuring the phase voltages between each midpoint and the neutral of the power grid;
comparing each of said measured phase voltages with a predetermined external threshold value; and
determining the occurrence of a malfunction of one of the external disconnecting devices if the phase voltage associated with one of the phases is greater than the predetermined external threshold value.

29. The verifying method according to claim 28, further comprising:
an internal verification step in which all the disconnecting devices are opened or kept open;
generating a known alternating voltage with the three-phase DC/AC converter;
measuring the phase voltages between each midpoint and the neutral of the power grid;
measuring the reference voltage;
adding the reference voltage to each of the phase voltages;
comparing the result of each sum with a predetermined internal threshold value; and
determining the occurrence of a malfunction of one of the internal disconnecting devices if the sum corresponding to its phase is greater than the predetermined internal threshold value.

30. The verifying method according to claim 29, further comprising:
an additional verification step in which all the internal disconnecting devices are closed or kept closed;
generating a known alternating voltage with the three-phase DC/AC converter;
measuring the phase voltages between each midpoint and the neutral of the power grid;
measuring the reference voltage;
adding the reference voltage to each of the measured phase voltages;
comparing the result of each sum with a predetermined additional threshold value; and
determining the occurrence of a malfunction of one of the internal disconnecting devices if the sum of its corresponding phase is less than the predetermined additional threshold value.

31. The verifying method according to claim 30, comprising:
a final verification step in which the internal disconnecting devices are open;
the external disconnecting devices are closed or kept closed;
measuring the phase voltages between each midpoint and the neutral of the power grid;
comparing said phase voltages with a predetermined final threshold value; and
determining the occurrence of a malfunction of one of the external disconnecting devices if the phase voltage corresponding to its phase is less than said final threshold value.

32. The verifying method according to claim 31, wherein the external verification step is carried out first, followed by the internal verification step, the additional verification step, and finally the final verification step.
